(19) United States
(12) Patent Application Publication
(10) Pub. No.: US 2019/0265299 A1
(43) Pub. Date: Aug. 29, 2019

(54) Monitoring And Fault Diagnosis Of Electric Machines

(71) Applicant: Siemens Aktiengesellschaft, Munchen (DE)

(72) Inventors: André Leppich, Herzogenaurach-Haundorf (DE); Markus Luft, Aschaffenburg (DE); Jürgen Rossmann, Gunzenhausen (DE); Alexander Stukenkemper, Cumming, GA (US)

(73) Assignee: Siemens Aktiengesellschaft, Munchen (DE)

(21) Appl. No.: 16/409,488

(22) Filed: May 10, 2019

Related U.S. Application Data
(63) Continuation-in-part of application No. 13/996,841, filed on Jun. 21, 2013.

(30) Foreign Application Priority Data
Dec. 21, 2010 (DE) 10 2010 063 759.9
Jul. 19, 2011 (DE) 10 2011 079 398.4

(51) Int. Cl. G01R 31/34

(52) U.S. Cl. CPC G01R 31/343

(57) ABSTRACT

In a method for monitoring a rotating electric machine (1) that is fed by a converter and for diagnosing faults of said rotating electric machine, a current signature (I1, I2, I3) of output signals of the converter is recorded, the current signature (I1, I2, I3) is transformed, and the transformed current signature (A) is evaluated in at least one frequency band in order to detect damage to the machine (1).

### CROSS-REFERENCE TO RELATED APPLICATIONS

This application is a Continuation-In-Part of U.S. application Ser. No. 13/996,841 filed Jun. 21, 2013, which is a U.S. National Stage Application of International Application No. PCT/EP2011/072224 filed Dec. 8, 2011, which designates the United States of America, and claims priority to DE Patent Application No. 10 2010 063 759.9 filed Dec. 21, 2010 and DE Patent Application No. 10 2011 079 398.4 filed Jul. 19, 2011, the contents of which are hereby incorporated by reference in their entirety.

### TECHNICAL FIELD

The invention relates to a method for monitoring and fault diagnosis of a rotating electric machine which is fed by a converter.

### BACKGROUND

State monitoring methods are known for monitoring and fault diagnosis of rotating electric machines in order to diagnose electrical or mechanical damage on such a machine.

EP 0 961 130 B1 discloses a method for the early detection of rotor damage in asynchronous machines, making use of two motor currents as measurement signals. In this situation a spectral analysis of said motor currents is carried out and used for detecting spectral disturbance components as characteristic values of the rotor damage.

### SUMMARY

According to various embodiments, an improved method for monitoring and fault diagnosis of a rotating electric machine which is fed by a converter can be specified.

According to an embodiment, in a method for monitoring and fault diagnosis of a rotating electric machine which is fed by a converter, a current signature of output signals of the converter is recorded, a transformation of the current signature is carried out and the transformed current signature is evaluated in at least one frequency band in order to detect damage to the machine, wherein the transformation of the current signature comprises at least one fast Fourier transform using a filter function.

According to a further embodiment, a transformed reference current signature can be ascertained which represents a damage-free state of the machine, and the transformed current signature can be compared during the evaluation with the transformed reference current signature. According to a further embodiment, in order to detect damage to the machine a frequency dependent tolerance band can be predetermined in a value range of the transformed current signature and damage is concluded to have occurred if the transformed current signature lies outside the tolerance band in the case of at least one frequency. According to a further embodiment, the tolerance band can be predetermined such that the transformed reference current signature lies within the tolerance band. According to a further embodiment, a damage-specific transformed current signature can be ascertained for at least one damage type, and that during the evaluation the transformed current signature is compared with at least one damage-specific transformed current signature. According to a further embodiment, a damage-specific transformed current signature can be ascertained at least for a broken rotor bar of a rotor of the machine or field asymmetry of the rotor or eccentricity of the rotor or a stator winding short-circuit of a stator of the machine or damage to a drive train of the machine. According to a further embodiment, all three phase currents can be recorded for a three-phase converter current and the transformation of the current signature comprises the formation of a symmetrical component from the three phase currents. According to a further embodiment, the transformation of the current signature may comprise an amplitude demodulation. According to a further embodiment, the amplitude demodulation can be carried out with a Hilbert transform of the Fourier transformed current signature. According to a further embodiment, the machine can be monitored continuously and automatically, and a fault report is automatically generated and/or an alarm is automatically triggered if damage to the machine is detected.

### BRIEF DESCRIPTION OF THE DRAWINGS

FIG. 1 shows a schematic view of an electric machine having an asynchronous motor,

FIG. 2 shows recorded current signatures of output signals of a converter which feeds an asynchronous motor,

FIG. 3 shows a transformed current signature of a converter which feeds a damage-free asynchronous motor,

FIG. 4 shows a transformed current signature of a converter which feeds an asynchronous motor having a broken rotor bar,

FIG. 5 shows a transformed current signature of a converter which feeds a damage-free asynchronous motor, in a first frequency band,

FIG. 6 shows a transformed current signature of a converter which feeds a damage-free asynchronous motor, in a second frequency band,

FIG. 7 shows a transformed current signature of a converter which feeds an asynchronous motor having a broken rotor bar, in a first frequency band, and

FIG. 8 shows a transformed current signature of a converter which feeds an asynchronous motor having a broken rotor bar, in a second frequency band.

Parts corresponding to one another are always identified by the same reference characters in all the figures.

### DETAILED DESCRIPTION

With regard to the method according to various embodiments for monitoring and fault diagnosis of a rotating electric machine which is fed by a converter, a current signature of output signals of the converter is recorded and a transformation of the current signature is carried out which comprises at least one fast Fourier transform using a filter function. The transformed current signature is evaluated in at least one frequency band in order to detect damage to the machine.

A current signature is understood here as being a timing characteristic of an electric current. Current signatures of output signals of a converter are accordingly understood here as being timing characteristics of electric currents which are output by the converter and supply an electrical machine fed by said converter.

The method thus involves the analysis of output signals (electrical currents) of a converter. The method advantageously utilizes that fact that even small levels of damage to a machine fed by converter affect the output signals of the converter and can therefore be detected by means of an analysis of said output signals. The use of a fast Fourier transform advantageously enables the detection of damage as a result of significant changes in the Fourier spectrum of the recorded output signals. The use of a filter function in this situation advantageously makes it possible to filter out noise signals and thereby simplifies the analysis of the Fourier spectrum.

The various embodiments thus enable the early detection of minor damage to a machine fed by converter, in other words before the machine is seriously damaged or completely destroyed. This means that minor damage can be eliminated in timely fashion and serious damage or destruction of the machine can be prevented. This also results in increased machine availability because the repair of serious damage or the replacement of a destroyed machine is time-consuming.

In an embodiment a transformed reference current signature is ascertained which represents a damage-free state of the machine, and the transformed current signature is compared during the evaluation with the transformed reference current signature.

Through comparison of the transformed current signature with the transformed reference current signature it is advantageously possible to quickly recognize damage to the machine as significant deviations from the transformed reference current signature.

Alternatively or in addition, in order to detect damage to the machine a frequency-dependent tolerance band is predetermined in a value range of the transformed current signature and damage is concluded to have occurred if the transformed current signature lies outside the tolerance band in the case of at least one frequency. In this situation the tolerance band is predetermined such that the transformed reference current signature lies within the tolerance band provided that one reference current signature has been ascertained.

The tolerance band specifies in a frequency-dependent fashion a range of values for the transformed current signature, for which the machine is assessed as being damage-free. As a result of predetermination of the tolerance band, damage to the machine can thus be rapidly and automatically diagnosed as soon as the transformed current signature departs from the tolerance band.

In a further additional or alternative embodiment, a damage-specific transformed current signature is ascertained for at least one damage type and during the evaluation the transformed current signature is compared with the at least one damage-specific transformed current signature.

In this manner, when using the method not only can damage to the machine be detected but it is also possible to conclude the nature of the damage if the transformed current signature matches a known damage-specific transformed current signature.

In this situation, a damage-specific transformed current signature is ascertained at least for a broken rotor bar of a rotor of the electric machine, for field asymmetry of the rotor, for eccentricity of the rotor, for a stator winding short-circuit of a stator of the electric machine or for damage to a drive train of the electric machine.

By this means the stated damage types can in particular be detected. This is advantageous because such types of damage frequently result in consequential damage to electrical machines to the point of their destruction.

Furthermore, all three phase currents are preferably recorded for a three-phase converter current and the transformation of the current signature comprises the formation of a symmetrical component from the three phase currents. A symmetrical component in this situation is understood to be a positive sequence component, a negative sequence component or a zero sequence component of the phase currents.

The formation and examination of a symmetrical component simplifies the analysis of a three-phase converter current compared with the analysis of the individual phase currents. In particular, it simplifies the analysis of an unbalanced fault in a three-phase system.

In addition, the transformation of the current signature preferably comprises an amplitude demodulation which for example is carried out with a Hilbert transform of the Fourier transformed current signature.

The amplitude demodulation facilitates the detection of significant changes in the transformed current signature and thus in the analysis thereof.

The electrical machine is furthermore preferably monitored continuously and automatically using the method according to various embodiments and a fault report is automatically generated and/or an alarm automatically triggered if damage to the machine is detected.

It is thereby advantageously possible to detect damage immediately after its appearance and consequential damage can be minimized.

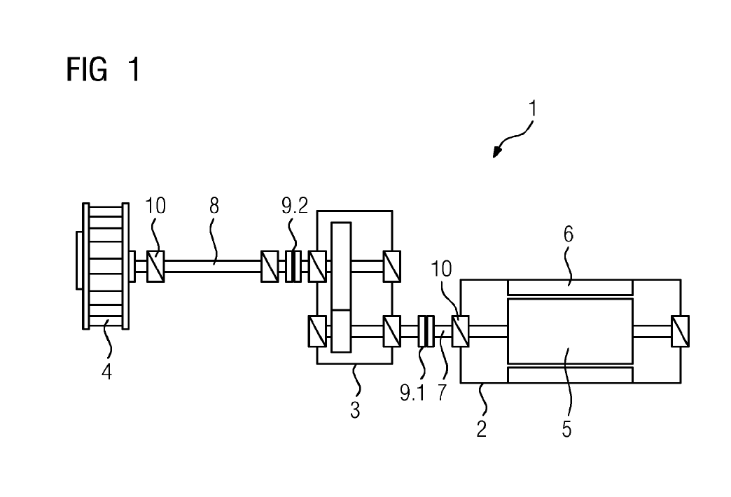

FIG. 1 shows a schematic view of an electric machine 1 having an asynchronous motor 2 operated with three-phase current, which drives a flywheel 4 by way of a gearing mechanism 3. The asynchronous motor 2 has a rotor 5 and a stator 6 and is fed by a converter which is not shown.

The rotor 5 is designed as a cage rotor having electrically conducting rotor bars.

The asynchronous motor 2 is connected by way of a drive shaft 7 and a first clutch unit 9.1 with the gearing mechanism 3. The gearing mechanism 3 and the flywheel 4 are connected with one another by way of a drive shaft 8 and a second clutch unit 9.2. The drive shaft 7 and the drive shaft 8 are mounted in bearings 10.

Different types of damage can occur to such a type of electric machine 1. These include rotor bar breakages of rotor bars of the rotor 5, field asymmetries of an electric field of the rotor 5, eccentricities of the rotor 5, in other words deviations of the alignment of the rotor axis from a nominal alignment, stator winding short-circuits, in other words—short-circuits of stator windings, bearing damage to bearings 10, alignment faults of components of a clutch unit 9.1, 9.2, gear faults of the gearing mechanism 3, damage to the drive shaft 7 or the drive shaft 8, or imbalance of the flywheel 4. Such types of damage can affect the electric current at an output from the converter which feeds the asynchronous motor 2 and therefore be detected by means of the method according to various embodiments.

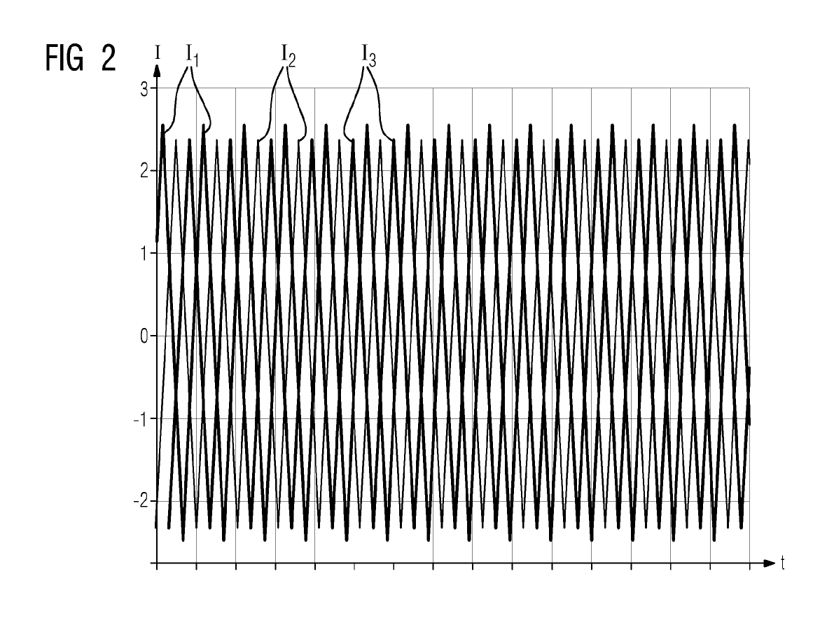

FIG. 2 shows recorded current signatures I.sub.1, I.sub.2, I.sub.3 of output signals of a converter which feeds an asynchronous motor 2 illustrated in FIG. 1. The current signatures may be recorded by a current sensor, e.g., an LEM-Flex™ AC current probe, which may be coupled to a computer processor configured to execute software to analyze the recorded current signatures to detect damage to the electrical machine, as discussed below. With regard to the current signatures I.sub.1, I.sub.2, I.sub.3, these each represent the characteristic of an electric current I dependent on a time t, with the i-th current signature I.sub.i specifying the timing characteristic of the i-th phase current of a three-phase current (where i=1, 2, 3).

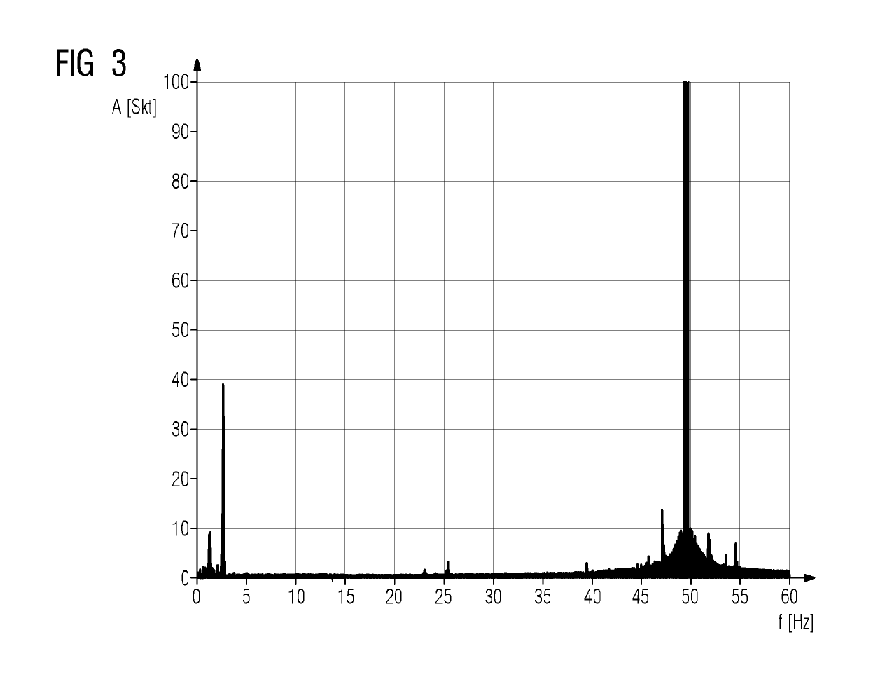

FIG. 3 shows a transformed current signature A which is generated by means of a fast Fourier transform of the first current signature I.sub.1 illustrated in FIG. 2 in the case of a damage-free electric machine 1. The transformed current signature A is used as a transformed reference current signature. It exhibits marked maxima in particular at frequencies of approximately 2.5 Hz and 49.5 Hz.

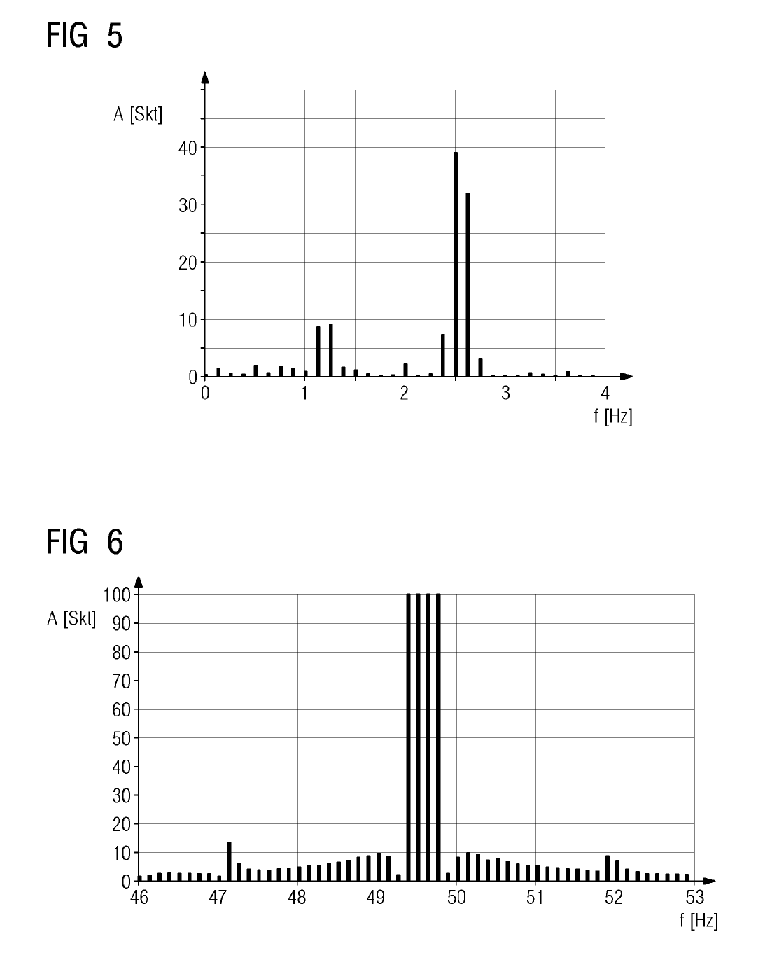

FIGS. 5 and 6 show the transformed reference current signature in a first frequency band from 0 Hz to 4 Hz and in a second frequency band from 46 Hz to 53 Hz respectively.

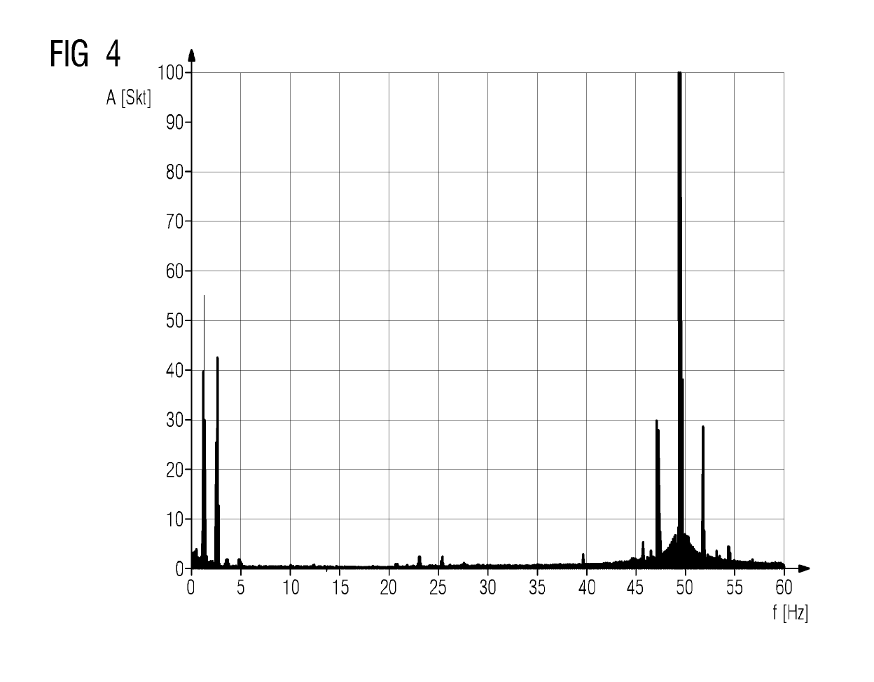

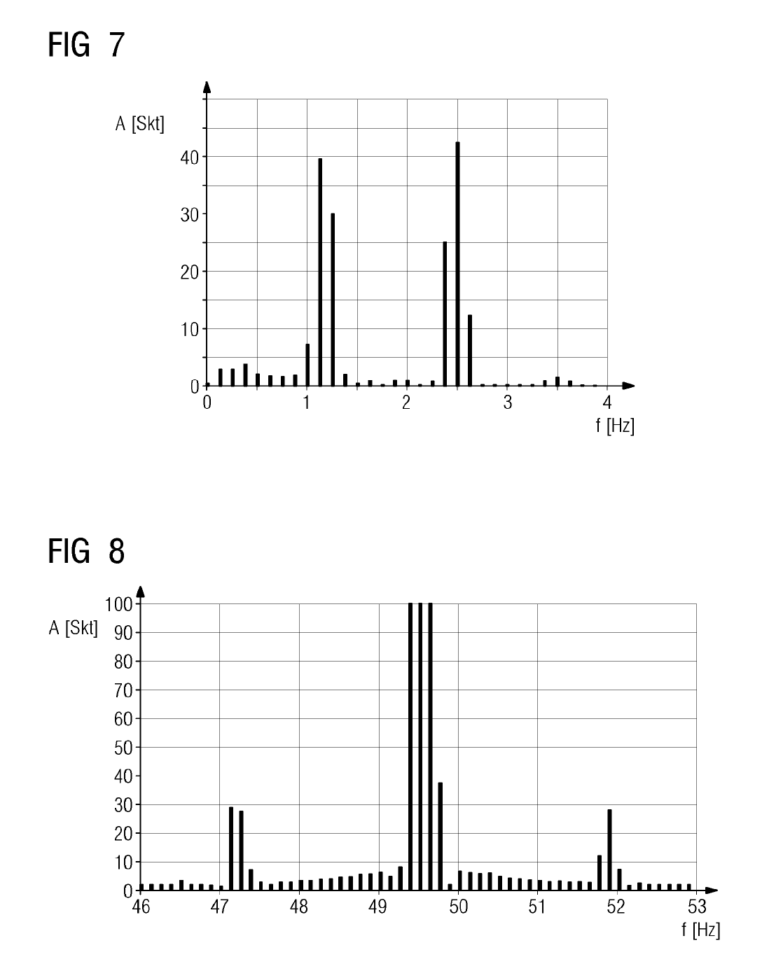

FIG. 4 shows a corresponding transformed current signature A of the first current signature I.sub.1 illustrated in FIG. 2, in which case the asynchronous motor 2 of the electric machine 1 has a rotor 5 with a broken rotor bar. FIGS. 7 and 8 show said transformed current signature A in the first frequency band from 0 Hz to 4 Hz and in the second frequency band from 46 Hz to 53 Hz respectively.

The transformed current signature A shown in FIGS. 4, 7 and 8 differs from the transformed reference current signature shown in FIGS. 3, 5 and 6 mainly as a result of significantly increased side lobes of the maximum at approximately 49.5 Hz which occur at frequencies of approximately 47 Hz and 52 Hz, and also a significantly increased maximum at approximately 1 Hz. These increased maxima are caused by the broken rotor bar and make it possible to detect the broken rotor bar by means of the transformed current signature A.

Other damage to the electric machine 1 can be detected in accordance with deviations characteristic in each case of said damage from the reference current signature shown in FIGS. 3, 5 and 6.

With regard to the transformed current signatures A shown in FIGS. 3 to 8, these are fast Fourier transforms of the current signature I.sub.1 of one phase current. As has already been described above, the method according to various embodiments can be modified and developed in various ways. In particular, a symmetrical component, in particular a negative sequence component, can be formed from the current signatures I.sub.1, I.sub.2, I.sub.3 of the three phase currents and evaluated accordingly. In addition, an amplitude demodulation can advantageously be carried out. Furthermore, the converter current can be broken down into a portion producing a field and a portion producing a torque and one or both of said portions can be analyzed.

The damage analysis process disclosed above-including receiving the three phase current signatures recorded by the current sensor, calculating a transformed current signature from the current signatures, comparing the current signature with reference data, and detecting a specific type of damage to the machine based on the comparison of the transformed current signature with the reference data—may be embodied in software stored in non-transitory computer-readable media and executable by a computer processor coupled to the current sensor. For example, the damage analysis may be performed by a SIPLUS CMS4000 condition monitoring system by SIEMENS™ for complex analysis and measurement tasks.

Although the invention has been illustrated and described in detail by means of a preferred exemplary embodiment, the invention is not restricted by the disclosed examples and other variations can be derived therefrom by the person skilled in the art without departing from the scope of protection of the invention

What is claimed is:

1. A method for monitoring and fault diagnosis of a rotating electric machine, including:
receiving input from a converter;
recording a current signature of output signals of the converter;
performing a transformation of the current signature to yield a transformed current signature, including performing at least one fast Fourier transform using a filter function;
determining a transformed reference current signature, the transformed reference current signature representing a damage-free state of the machine; and
evaluating the transformed current signature in at least one frequency band in order to detect damage to the machine, including:
applying a frequency dependent tolerance band predetermined in a value range of the transformed current signature, wherein the frequency dependent tolerance band is predetermined such that the transformed reference current signature lies within the frequency dependent tolerance band; and
determining that damage has occurred based on a determination that transformed current signature lies outside the frequency dependent tolerance band in the case of at least one frequency.

2. The method according to claim 1, wherein, in the evaluation for the transformed current signature at least one particular type of damage is determined for a current transformed feature.

3. The method according to claim 2, wherein the current transformed feature is determined by comparing transformed current signature with a reference in the evaluation of the transformation.

4. The method according to claim 1, wherein the damage determined to the machine includes determining a rotor bar break of rotor bars of a rotor, field asymmetries of an electric field of a rotor, or eccentricities of a rotor based on upon particular current characteristics to the type of damage.

5. The method according to claim 1, wherein the input is a three-phase converter current and the transformed current signature includes a component formed by the symmetrical three-phase current.

6. The method according to claim 5, wherein the transformed current signature includes components of a symmetrical three-phase current.

7. The method according to claim 1, wherein a characteristic of the input comprises amplitude modulation.

8. The method according to claim 1, further comprising performing a fast Fourier transform of Hilbert transform of amplitude modulation of the input.

9. The method according to claim 1, further comprising automatically and continuously monitoring the machine, and when damage is detected, automatically generating an alert.
